(19) United States
(12) Patent Application Publication
(10) Pub. No.: US 2025/0076749 A1
(43) Pub. Date: Mar. 6, 2025

(54) OPC METHOD AND MASK MANUFACTURING METHOD INCLUDING OPC METHOD

(71) Applicant: SAMSUNG ELECTRONICS CO., LTD., Suwon-si (KR)

(72) Inventors: Yeojin NA, Suwon-si (KR); Jongdoo Kim, Suwon-si (KR); Juyun Park, Suwon-si (KR)

(73) Assignee: SAMSUNG ELECTRONICS CO., LTD., Suwon-si (KR)

(21) Appl. No.: 18/646,070

(22) Filed: Apr. 25, 2024

(30) Foreign Application Priority Data
Aug. 30, 2023 (KR) 10-2023-0114606

(51) Int. Cl. G03F 1/36; G03F 1/76

(52) U.S. Cl. CPC G03F 1/36; G03F 1/76

(57) ABSTRACT

Provided are an optical proximity correction (OPC) method and a mask manufacturing method including the OPC method for implementing a simulation contour more stiffly to ensure a processing margin. The OPC method includes receiving a design layout for a target pattern, obtaining an OPC pattern by performing first OPC on the design layout, extracting a transition area as an area having a width that changes from a first width to a second width, which is less than the first width, from the target pattern, obtaining a simulation contour for the transition area, calculating at least one of a correction length and a correction angle based on the simulation contour, obtaining a first OPC pattern for the transition area based on at least one of the correction length and the correction angle, and obtaining a final OPC pattern by merging the first OPC pattern with the OPC pattern.

### CROSS-REFERENCE TO RELATED APPLICATION

This application is based on and claims priority under 35 U.S.C. § 119 to Korean Patent Application No. 10-2023-0114606, filed on Aug. 30, 2023, in the Korean Intellectual Property Office, the disclosure of which is incorporated by reference herein in its entirety.

### BACKGROUND

### 1. Field

The disclosure relates to a mask manufacturing method, and more particularly, to an optical proximity correction (OPC) method and a mask manufacturing method including the OPC method.

### 2. Description of Related Art

In a semiconductor manufacturing process, a photolithography process using a mask may be performed to form a pattern on a semiconductor substrate, such as a wafer. Simply defined, a mask may be stated to be a pattern transfer material in which a pattern shape of an opaque material is formed on a transparent base material. To briefly explain a mask manufacturing process, first, a required circuit is designed and a layout for the circuit is designed, and then design data obtained through optical proximity correction (OPC) is delivered as mask tape-out (MTO) design data. Thereafter, mask data preparation (MDP) may be performed based on the MTO design data, and an exposure process and the like may be performed on a substrate for the mask.

### SUMMARY

The disclosure provides an optical proximity correction (OPC) method and a mask manufacturing method including the OPC method for implementing a simulation contour more stiffly to ensure a processing margin.

Additional aspects will be set forth in part in the description which follows and, in part, will be apparent from the description, or may be learned by practice of the disclosure.

According to an aspect of the disclosure, an optical proximity correction (OPC) method includes: receiving a design layout for a target pattern; obtaining an OPC pattern by performing first OPC on the design layout; extracting a transition area from the target pattern, wherein the transition area comprises a width that changes from a first width in a first portion to a second width in a second portion, and the second width is less than the first width; obtaining a simulation contour for the transition area; calculating at least one of a correction length and a correction angle based on the simulation contour; obtaining a first OPC pattern for the transition area based on at least one of the correction length and the correction angle; and obtaining a final OPC pattern by merging the first OPC pattern with the OPC pattern, wherein the first portion comprises a common lower horizontal line extending in a first direction, a first upper horizontal line parallel to the common lower horizontal line, and a vertical line extending in a second direction from an end of the first upper horizontal line, wherein the second direction intersects the first direction, wherein the second portion is in contact with the first portion and comprises the common lower horizontal line and a second upper horizontal line parallel to the common lower horizontal line and connected to the vertical line, and wherein the first width and the second width are distances from the common lower horizontal line to the first upper horizontal line and from the common lower horizontal line to the second upper horizontal line, respectively.

According to an aspect of the disclosure, an optical proximity correction (OPC) method includes: receiving a design layout for a target pattern; obtaining an OPC pattern by performing first OPC on the design layout; extracting a transition area from the target pattern, wherein the transition area comprises a width that changes from a first width in a first portion to a second width in a second portion, and the second width is less than the first width; obtaining a simulation contour for the transition area; calculating a correction length based on the simulation contour; primarily obtaining a first OPC pattern for the transition area based on the correction length; calculating a correction angle based on the simulation contour; secondarily obtaining the first OPC pattern for the transition area based on the correction angle; and obtaining a final OPC pattern by merging the first OPC pattern with the OPC pattern, wherein the first portion comprises a common lower horizontal line extending in a first direction, a first upper horizontal line parallel to the common lower horizontal line, and a vertical line extending in a second direction from an end of the first upper horizontal line, wherein the second direction intersects the first direction, wherein the second portion is in contact with the first portion and comprises the common lower horizontal line and a second upper horizontal line parallel to the common lower horizontal line and connected to the vertical line, and wherein the first width and the second width are distances from the common lower horizontal line to the first upper horizontal line and from the common horizontal line to the second upper horizontal line, respectively.

According to an aspect of the disclosure, a mask manufacturing method includes: receiving a design layout for a target pattern; obtaining an optical proximity correction (OPC) pattern by performing first OPC on the design layout; extracting a transition area from the target pattern, wherein the transition area comprises a width that changes from a first width in a first portion to a second width in a second portion, and wherein the second width is less than the first width; obtaining a simulation contour for the transition area; calculating at least one of a correction length and a correction angle based on the simulation contour; obtaining a first OPC pattern based on the at least one of the correction length and the correction angle; obtaining a final OPC pattern by merging the first OPC pattern with the OPC pattern; transferring data on the final OPC pattern as mask tape-out (MTO) design data; preparing mask data based on the MTO design data; and performing exposure on a substrate for a mask based on the mask data.

### BRIEF DESCRIPTION OF DRAWINGS

Embodiments of the disclosure will be more clearly understood from the following detailed description taken in conjunction with the accompanying drawings in which:

FIG. 1 is a schematic flowchart of processes of an optical proximity correction (OPC) method according to an embodiment;

FIG. 2 is a flowchart showing in more detail an operation of calculating a correction length and an operation of obtaining a first OPC pattern for a transition area based on the correction length in the OPC method of FIG. 1;

FIGS. 3A, 3B, and 3C are conceptual diagrams showing a target pattern, a simulation contour, and a first OPC pattern corresponding to each operation of the flowchart of FIG. 2;

FIG. 4 is a flowchart showing in more detail an operation of calculating a correction angle and an operation of obtaining a first OPC pattern for a transition area based on the correction angle in the OPC method of FIG. 1;

FIGS. 5A, 5B, 5C, 5D, 5E, and 5F are conceptual diagrams showing a target pattern, a simulation contour, and a first OPC pattern corresponding to each operation of the flowchart of FIG. 4;

FIGS. 6A and 6B are a transmission electron microscope (TEM) image and an enlarged TEM image of detailed patterns to which an OPC method according to an embodiment is applicable;

FIG. 7 is a schematic flowchart of processes of an OPC method according to an embodiment; and

FIG. 8 is a schematic flowchart of processes of a mask manufacturing method including an OPC method according to an embodiment.

### DETAILED DESCRIPTION

Hereinafter, the disclosure will be described in detail by explaining embodiments with reference to the attached drawings. Like reference numerals in the drawings denote like elements, and a repeated description is omitted.

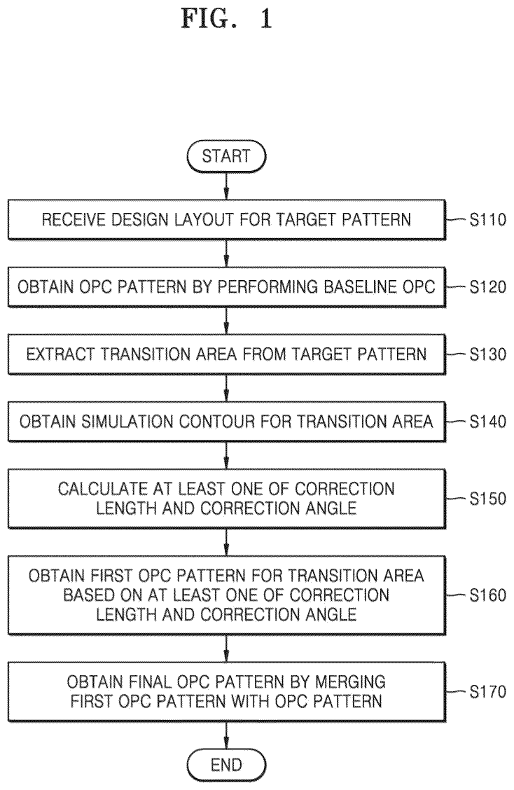

FIG. 1 is a schematic flowchart of processes of an optical proximity correction (OPC) method according to an embodiment.

Referring to FIG. 1, in the OPC method according to the present disclosure, a design layout for a target pattern to be formed on a substrate is received (S110). Here, the target pattern may refer to a pattern to be formed on a silicon (Si) substrate such as a wafer. In other words, a pattern on a mask may be transferred to the substrate through an exposure process to form the target pattern on the substrate. Usually, the pattern on the mask is projected to be reduced and transferred onto the wafer, and thus the pattern on the mask may have a larger size than the target pattern on the substrate.

The design layout may refer to a layout for the pattern on the mask, corresponding to the target pattern. Due to the characteristics of the exposure process, a shape of the target pattern on the wafer and a pattern on an actual mask used in the exposure process may be different from each other. However, a shape of an initial design layout for the pattern on the mask may be substantially the same as the shape of the target pattern.

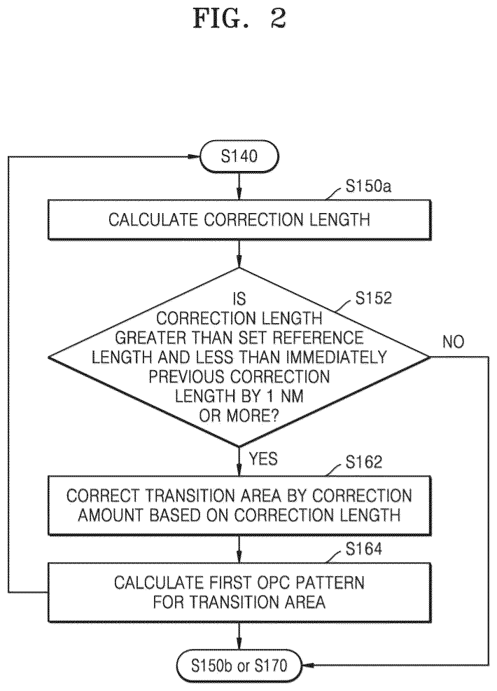

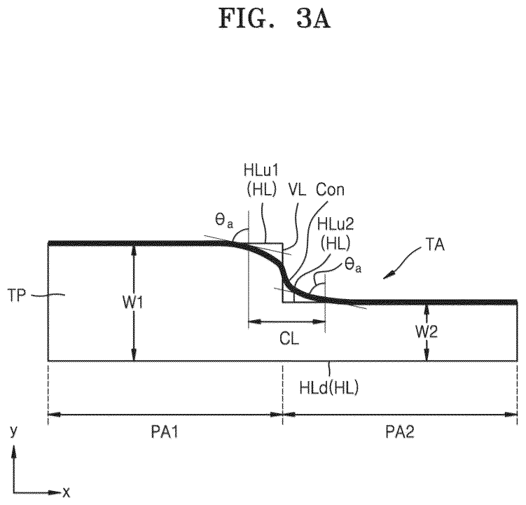

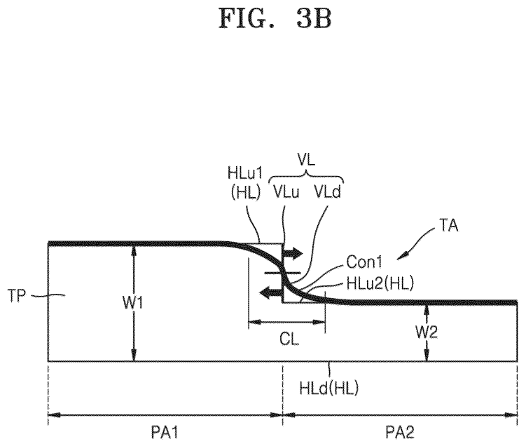

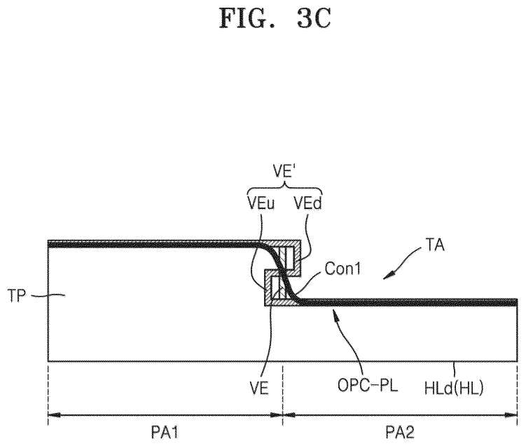

In the OPC method according to the present disclosure, the target pattern may include a transition area. The transition area may refer to an area having a width that changes from a large width to a small width. The transition area will be described in more detail with reference to FIGS. 2 to 3C.

After the design layout is received, baseline OPC may be performed on the design layout to obtain an OPC pattern (S120). The baseline OPC may refer to typical OPC to implement patterning closest to the target pattern on the substrate. For reference, the OPC refers to a method of preventing an optical proximity effect (OPE) from occurring by correcting a design layout of a pattern on a mask to overcome a problem wherein the OPE occurs due to an influence between neighboring patterns during an exposure process as patterns are miniaturized.

To explain the baseline OPC process in general, the baseline OPC process is largely divided into two processes including a rule-based OPC process and a simulation-based or model-based OPC process. The model-based OPC process may have reduced time and cost by using the measurement results of representative patterns alone without a need to measure all of a large number of test patterns.

The baseline OPC process may include not only a method of changing a layout of a pattern but also a method of adding sub-lithographic features called serifs on corners of the pattern or adding sub-resolution assist features (SRAFs) such as scattering bars.

For performing the baseline OPC process, first, basic data for OPC is prepared. Here, the basic data may include data of shapes of patterns, positions of the patterns, a type of measurement such as measurement for a space or line of a pattern, and a basic measurement, for a sample. In addition, the basic data may include information of a thickness, refractive index, and dielectric constant of a photoresist (PR), and may include a source map for the form of an illumination system. The basic data may not be limited to the above-mentioned data.

After the basic data is prepared, an optical OPC model is generated. The generation of the optical OPC model may include optimization of a defocus stand (DS) position and best focus (BF) position, or the like, in the exposure process. In addition, the generation of an optical OPC model may include generation of an optical image considering diffraction of light or an optical state of the exposure equipment itself. The generation of the optical OPC model is not limited to the above description. For example, the generation of the optical OPC model may include various contents related to an optical phenomenon in the exposure process.

After the optical OPC model is generated, an OPC model for a PR is generated. The generation of the OPC model for the PR may include optimization of a threshold of the PR. Here, the threshold of the PR refers to a threshold at which a chemical change occurs in the exposure process, and for example, the threshold may be given as intensity of exposure light. The generation of the OPC model for the PR may also include selecting an appropriate model form from several PR model forms.

A combination of the optical OPC model and the OPC model for the PR is generally called an OPC model. After the OPC model is generated, simulation using the OPC model is performed to obtain an OPC pattern, i.e., an OPCed design layout. Then, the OPCed design layout may be handed over to a mask production team as mask tape-out design data for mask production.

The obtaining of an OPC pattern may include an operation of minimizing an edge placement error (EPE) by comparing a simulation contour to a target pattern. The EPE refers to a difference between an edge of the target pattern and the simulation contour, and is usually calculated in each set of evaluation points. The simulation contour is the result of simulation using the OPC model, which may correspond to a shape of the target pattern formed on the wafer in the exposure process using a mask. Thus, it is an object of the OPC process to make the simulation contour as similar as possible to the shape of the target pattern.

After the EPE is calculated, the operation of minimizing the EPE may be performed by moving segments to reduce the EPE and obtain a new OPC pattern, and calculating the EPE by comparing the simulation contour with the target pattern again. Generally, the operation of minimizing the EPE may be repeated until the EPE is a set reference value or less or may be repeated a set number of repeated times. For reference, a segment may also be known as a fragment and may mean a straight line corresponding to the edge of the design layout or data on the line. The edge of the design layout may be divided into a plurality of segments by a certain sharing rule. The length of the segment and the sharing rule may be set by a user who performs the OPC method.

In general, the baseline OPC process has no consideration for the transition area. Therefore, a significant corner rounding phenomenon may occur in the transition area. The corner rounding phenomenon is a phenomenon in which rounding occurs in a corner portion of a pattern in the exposure process due to a limit of resolution, which may act as a major cause of reducing a processing margin. Usually, when the corner rounding phenomenon is explained, a corner rounding radius (CRR) may be defined. For example, the CRR may be defined by points at which the simulation contour first intersects with the target pattern from the corner position of the target pattern. When the CRR has a large value, the corner rounding phenomenon is stated to be large, and when the CRR has a small value, the corner rounding is stated to be small.

As described below, the OPC method according to the present disclosure may include an operation of obtaining a first OPC pattern by correcting the transition area based on a correction length and/or a correction angle for the transition area. Accordingly, the OPC method according to the present disclosure may minimize the corner rounding phenomenon by optimizing or improving the CRR, thereby ensuring a sufficient processing margin.

After the OPC pattern is obtained, the transition area is extracted from the target pattern (S130). As described above, the transition area may refer to an area having a width that changes from a large width to a small width. As numerous defects are typically generated in the transition area, the transition area may be referred to as a weak-points area.

After the transition area is extracted, the simulation contour is obtained for the transition area (S140). In other words, simulation using the OPC model is performed and the simulation contour for the OPC pattern corresponding to the transition area is obtained.

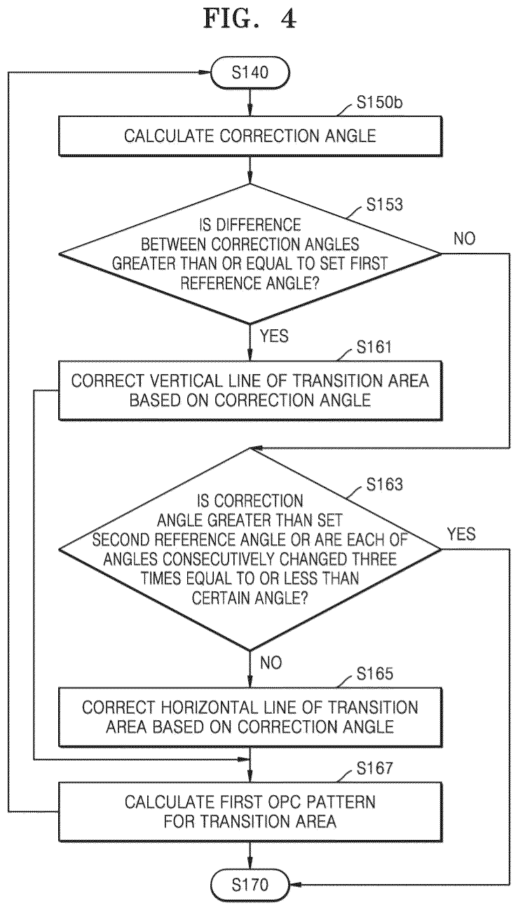

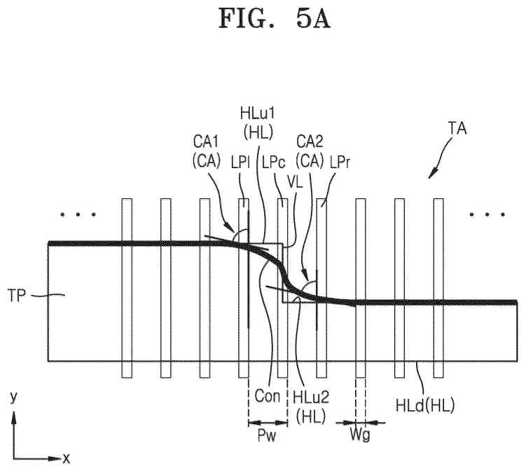

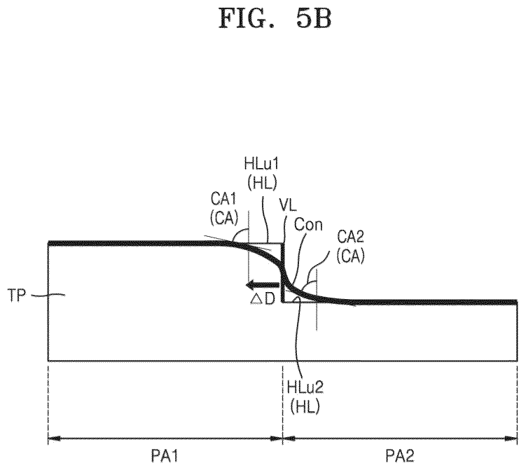

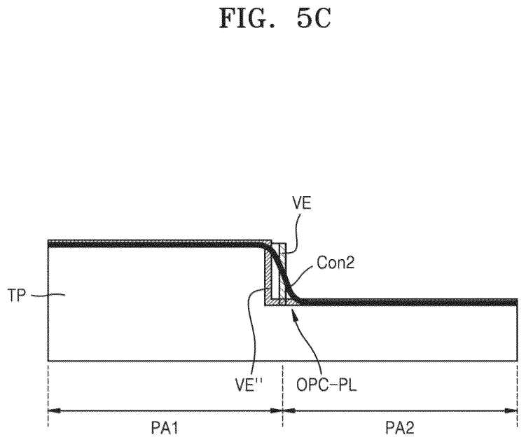

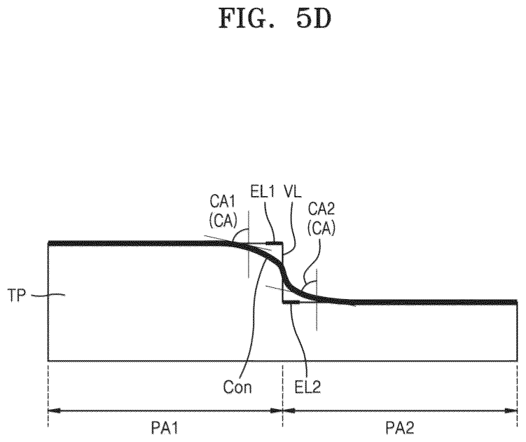

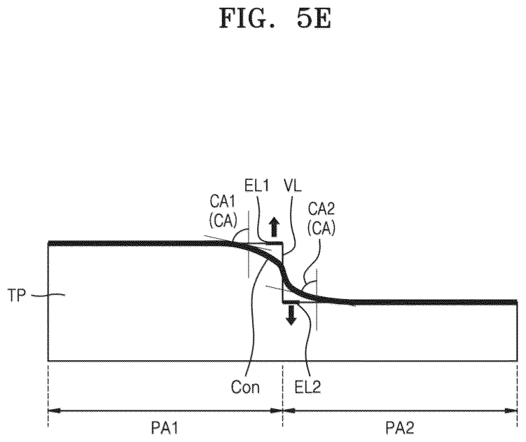

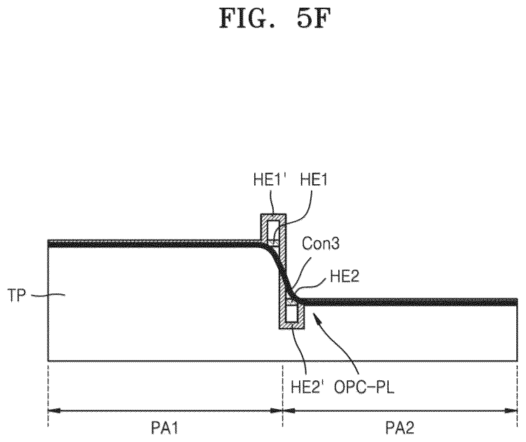

After the simulation contour is obtained, at least one of the correction length and the correction angle is calculated (S150). The process of defining and calculating the correction length is described in detail in the description of FIGS. 2 through 3C, and the process of defining and calculating the correction angle is described in detail in the description of FIGS. 4 through 5F.

Then, based on at least one of the correction length and the correction angle, a first OPC pattern for the transition area is obtained (S160). The operation of obtaining a first OPC pattern based on the correction length is described in detail in the description of FIGS. 2 through 3C, and the operation of obtaining a first OPC pattern based on the correction angle is described in detail in the description of FIGS. 4 through 5F.

Operation S150 of calculating at least one of the correction length and the correction angle, and operation S160 of obtaining the first OPC pattern based on the at least one of the correction length and the correction angle, may be performed selectively or in combination. Specifically, when the operations are performed selectively, one of the operation of calculating the correction length and the operation of obtaining the first OPC pattern based on the correction length, and the operation of calculating the correction angle and the operation of obtaining the first OPC pattern based on the correction angle may be performed alone. On the other hand, when the operations are performed in combination, both the operation of calculating the correction length and the operation of obtaining the first OPC pattern based on the correction length, and the operation of calculating the correction angle and the operation of obtaining the first OPC pattern based on the correction angle, may be performed. Alternatively, when the operations are performed in combination, the operation of calculating the correction length and the operation of obtaining the first OPC pattern based on the correction length may be first performed, and then the operation of calculating the correction angle and the operation of obtaining the first OPC pattern based on the correction angle may be performed. However, the order is not limited thereto. For example, in one or more embodiments, the operations may be performed in reverse order or simultaneously.

After the first OPC pattern is obtained, the first OPC pattern is merged with an OPC pattern for the entire previous target pattern to obtain a final OPC pattern (S170). The final OPC pattern may be a finally OPCed design layout and may correspond to design data for mask production. Thus, the final OPC pattern may be handed over to a mask production team as MTO design data for mask production.

FIG. 2 is a flowchart showing in more detail the operation of calculating the correction length and the operation of obtaining the first OPC pattern for the transition area based on the correction length in the OPC method of FIG. 1. FIGS. 3A through 3C are conceptual diagrams showing a target pattern, a simulation contour, and a first OPC pattern corresponding to each operation of the flowchart of FIG. 2. The method will be described with reference to the drawings with FIG. 1, and content already explained in the description of FIG. 1 is briefly explained or omitted.

Referring to FIGS. 2 and 3A, after operation S140 of obtaining a simulation contour, a correction length CL in a transition area TA is calculated (S150a). When the target pattern TP extends in an x direction, the transition area TA may mean an area having a y-direction width that changes from a first width W1 in a first portion PA1 to a second width W2 in a second portion PA2, which is less than the first width W1. Specifically, the first portion PA1 may include a common lower horizontal line HLd extending in the x direction, a first upper horizontal line HLu1 parallel to the common lower horizontal line HLd, and a vertical line VL extending in the y direction from an end of the first upper horizontal line HLu1. The second portion PA2 may be in contact with the first portion PA1 and may include the common lower horizontal line HLd, and a second upper horizontal line HLu2 parallel to the common lower horizontal line HLd and connected to the vertical line VL. The first portion PA1 and the second portion PA2 may be defined in the range in which the correction length CL is calculated based on the vertical line VL, and the transition area TA may include the first portion PA1 and the second portion PA2.

The correction length CL may be calculated as follows. First, the simulation contour Con may be obtained for an OPC pattern corresponding to the transition area TA. Then, the correction length CL may be calculated as a distance in the x direction between two points having a reference length extraction angle θa set for the vertical line VL based on a tangent line for the simulation contour Con. As seen from FIG. 3A, the simulation contour Con changes with an inflection point in a portion of the vertical line VL, and thus there may be two points having the reference length extraction angle θa on both sides of the vertical line VL in the x direction. The reference length extraction angle θa may be set in a range of, for example, about 80° to about 90°. However, the range in which the reference length extraction angle θa is set may not be limited to the above numerical range.

Referring to FIGS. 2 and 3B, after the correction length CL is calculated, it is determined whether the correction length CL is greater than a set reference length and is less than an immediately previous correction length by 1 nm or more is determined (S152). The reference length may be set in a range of, for example, several nm to tens of nm. However, the range in which the reference length is set is not limited to the above numerical range. When calculation of the correction length CL is initial, whether the correction length CL is less than an immediately previous correction length by 1 nm or more may not be determined.

When the correction length CL is greater than a set reference length and is less than an immediately previous correction length by 1 nm or more (YES), the transition area TA is corrected by a correction amount based on the correction length CL (S162). For example, the correction amount may be calculated through Equation 1 below.

$$Correction amount = FB * ( correction length - reference length ) / 2 \qquad Equation 1$$

With regard to Equation 1, FB is a feedback factor, which may be set in a range of 0 to 1. However, the range of the FB is not limited to the above numerical range. For example, when the reference length is 30 nm, the correction length is calculated to be 34 nm, and the FB is 0.5, a correction amount of 1 nm is obtained via Equation 1 (i.e., 0.5*(34−30)/2=1).

After the correction amount is calculated, the vertical line VL is equally divided into an upper vertical line VLu and a lower vertical line VLd. Subsequently, the upper vertical line VLu is moved by the correction amount toward the second portion PA2, and the lower vertical line VLd is moved by the correction amount toward the first portion PA1. Through this method, the transition area TA may be corrected by moving the upper vertical line VLu and the lower vertical line VLd.

Referring to FIGS. 2 and 3C, the first OPC pattern for the corrected transition area TA is calculated (S164). In FIG. 3C, a line OPC-PL of the first OPC pattern corresponding to a horizontal line HL and the vertical line VL on the corrected transition area TA is indicated by a dark hatched line. In FIG. 3C, a vertical edge VE (lightly hatched) of an OPC pattern corresponding to an existing vertical line VL and a vertical edge VE′ of the first OPC pattern corresponding to the corrected vertical line VL are shown together. The vertical edge VE′ of the first OPC pattern may include an upper vertical edge VEu and a lower vertical edge VEd correspondingly to the moved upper vertical line VLu and lower vertical line VLd.

After the first OPC pattern is calculated, a simulation contour is obtained (S140). In operation S140, the simulation contour may be obtained again for the first OPC pattern of the corrected transition area TA. As seen from FIG. 3C, a new simulation contour Con1 is shown, and the new simulation contour Con1 changes more steeply in a portion of the vertical line VL compared to the previous simulation contour Con.

Subsequently, operation S150a of calculating the correction length and operation S152 of determining the correction length may be performed. For example, in operation S152 of determining the correction length, when the newly calculated correction length is greater than the reference length and is less than an immediately previous correction length by 1 nm or more (YES), the method may proceed to operation S162 of correcting the transition area. When the newly calculated correction length is equal to or less than the reference length or is less than the immediately previous correction length by less than 1 nm (NO), the method may proceed to operation S170 of obtaining a final OPC pattern or operation S150b of calculating the correction angle. For example, in the OPC method of FIG. 1, when operation S160 of obtaining the first OPC pattern is selectively performed, the method may proceed to operation S170 of obtaining the final OPC pattern, and when operation S160 of obtaining the first OPC pattern are performed in combination, the method may proceed to operation S150b of calculating the correction angle.

FIG. 4 is a flowchart showing in more detail the operation of calculating the correction angle and the operation of obtaining the first OPC pattern for the transition area based on the correction angle in the OPC method of FIG. 1. FIGS. 5A through 5F are conceptual diagrams showing a target pattern, a simulation contour, and a first OPC pattern corresponding to each operation of the flowchart of FIG. 4. The method will be described with reference to the drawings with FIG. 1, and content already explained in the description of FIG. 1 is briefly explained or omitted.

Referring to FIGS. 4 and 5A, after operation S140 of obtaining a simulation contour, a correction angle CA in a transition area TA is calculated (S150b). When operation S160 of obtaining of the first OPC pattern is performed in combination, operation S150b of calculating the correction angle CA may be performed after the operation of obtaining the first OPC pattern for the transition area TA based on the correction length CL described above with reference to FIGS. 2 to 3C. In operation S150b of calculating the correction angle CA in the transition region TA, the transition area TA, the first portion PA1, and the second portion PA2 are the same as the description of FIGS. 2 to 3C.

The correction angle CA may be calculated as follows. First, the simulation contour Con for the OPC pattern corresponding to the transition area TA is obtained. Then, when line patterns that extend in the y direction and have a constant pitch in the x direction are arranged for the transition area TA, first and second line patterns LPl and LPr are extracted from the line patterns. Then, first and second angles CA1 and CA2 between a tangent line of the simulation contour Con and the first and second line patterns LPl and LPr at points at which the first and second line patterns LPl and LPr intersect with the simulation contour Con may be calculated as the correction angle CA.

For a central line pattern LPc corresponding to the vertical line VL among the line patterns, a first line pattern to the left may be extracted as a first line pattern LPl and a first line to the right may be extracted as a second line pattern LPr. As shown in FIG. 5A, in the case of the central line pattern LPc, the center in the x direction may substantially match the vertical line VL. In addition, a first angle CA1 may be calculated at the right side of the first line pattern LPl, and a second angle CA2 may be calculated at the left side of the second line pattern LPr. Therefore, when a position of the vertical line VL in the x direction is 0, positions at which the first and second angles CA1 and CA2 are calculated may correspond to (Pw−Wg/2) and + (Pw−Wg/2), respectively. Pw may correspond to a pitch of the line patterns in the x direction, and Wg may correspond to a width of the line pattern in the x direction.

Referring to FIGS. 4 and 5B, after the correction angle CA is calculated, whether a difference between correction angles is greater than or equal to a set first reference angle may be determined (S153). In other words, it is determined whether a difference between the first angle CA1 and the second angle CA2 is greater than or equal to the first reference angle. The first reference angle may be set in a range of about 0° to about 10°. However, the range in which the first reference length is set is not limited to the above numerical range.

When the difference in correction angles is greater than or equal to the first reference angle (YES), the vertical line VL of the transition area TA is corrected based on the correction angle (S161). The vertical line VL may be corrected by moving the vertical line VL to a larger angle of the first angle CA1 and the second angle CA2 by a first distance ΔD. For example, in FIG. 5B, the first angle CA1 may be greater than the second angle CA2, and the difference between the first angle CA1 and the second angle CA2 may be greater than the first reference angle. Accordingly, the vertical line VL may be moved to the left by the first distance ΔD. The first distance ΔD may be equal to or less than 1 nm. However, the first distance ΔD is not limited to the above numerical range.

When the difference between correction angles is less than the first reference angle (NO), the method may proceed to operation S163 of comparing the correction angles with a second reference angle. Operation S163 of comparing the correction angles with the second reference angle will be described in detail with reference to FIGS. 5D through 5F.

Referring to FIGS. 4 and 5C, after the vertical line VL of the transition area TA is corrected, the first OPC pattern for the corrected transition area TA is calculated (S167). In FIG. 5C, a line OPC-PL of the first OPC pattern corresponding to the horizontal line HL and the vertical line VL on the corrected transition area TA is indicated by a dark hatched line. In FIG. 5C, a vertical edge VE (lightly hatched) of an OPC pattern corresponding to an existing vertical line VL and a vertical edge VE″ of the first OPC pattern corresponding to the corrected vertical line VL are shown together.

After the first OPC pattern is calculated, the method may proceed to operation S140 of obtaining the simulation contour. In operation S140 of obtaining the simulation contour, the simulation contour may be obtained again for the first OPC pattern of the corrected transition area TA. As seen from FIG. 5C, a new simulation contour Con2 is shown, and the new simulation contour Con1 changes more steeply in a portion of the vertical line VL compared to the previous simulation contour Con.

Subsequently, operation S150b of calculating the correction angle and operation S153 of determining the correction angle may be performed. For example, in operation S153 of determining the correction angle, when the newly calculated correction angle is greater than or equal to the first reference angle (YES), the method may proceed to operation S161 of correcting the vertical line VL. On the other hand, when the newly calculated correction angle is less than the first reference angle (NO), the method may proceed to operation S163 of comparing the correction angle with the second reference angle. In one or more embodiments, operation S165 of correcting the horizontal line HL may not be performed; and, in such an embodiment, when the correction angle is less than the first reference angle (NO), the method may proceed to operation S170 of obtaining the final OPC pattern without proceeding to operation S163 of comparing the correction angle with the second reference angle.

Referring to FIGS. 4 and 5D, in operation S153 of determining the correction angle, when the correction angle is less than the first reference angle (NO), whether the correction angle is greater than the set second reference angle or each of angles consecutively changed three times is equal to or less than a certain angle may be determined (S163). The second reference angle may be set in a range of, for example, about 80° to about 90°. However, the range in which the second reference angle is set is not limited to the above numerical range. Comparison with the second reference angle may be performed for both the first angle CA1 and the second angle CA2. The certain angle may be set to less than 1°. However, the range of the certain angle is not limited to the above numerical range. A determination of whether the angles consecutively changed three times may be performed after correction for the horizontal line HL is performed three times or more.

When both the first angle CA1 and the second angle CA2 are each greater than the second reference angle (YES), the method may proceed to operation S170 of obtaining the final OPC pattern. When each of the angles consecutively changed three times is equal to or less than a certain angle (YES), the method may also proceed to operation S170 of obtaining the final OPC pattern.

However, when at least one of the first angle CA1 and the second angle CA2 is less than the second reference angle (NO), the horizontal line HL of the transition area TA is corrected based on the correction angle (S165). That is, when the first angle CA1 is less than the second reference angle, the second angle CA2 is less than the second reference angle, or both the first angle CA1 and the second angle CA2 are each less than the second reference angle, the method may proceed to operation S163 of correcting the horizontal line HL of the transition area TA.

Referring to FIGS. 4, 5D, and 5E, the operation of correcting the horizontal line HL may be performed as follows. First, first and second edge lines EL1 and EL2 are set. For example, a portion of the first upper horizontal line HLu1 between the central line pattern LPc and the first line pattern LPl is set to the first edge line EL1, and a portion of the second upper horizontal line HLu2 between the central line pattern LPc and the second line pattern LPr is set to the second edge line EL2. Each of the first and second edge lines EL1 and EL2 may be set to about ½ of a pitch Pw of line patterns in the x direction from the vertical line VL. However, the length of the first and second edge lines EL1 and EL2 is not limited thereto. For example, in one or more embodiments, each of the first and second edge lines EL1 and EL2 may be set to a length of the pitch Pw of line patterns in the x direction from the vertical line VL.

After the first and second edge lines EL1 and EL2 are set, the horizontal line HL of the transition area TA may be corrected by moving the first and second edge lines EL1 and EL2 corresponding to a correction angle less than the second reference angle in the y direction away from the vertical line VL. For example, when the first angle CA1 is less than the second reference angle, the first edge line EL1 may be moved upward in the y direction away from the vertical line VL. When the second angle CA2 is less than the second reference angle, the second edge line EL2 may be moved downward in the y direction away from the vertical line VL. When both the first angle CA1 and the second angle CA2 are each less than the second reference angle, the first and second edge lines EL1 and EL2 may be moved upward and downward, respectively, in the y direction away from the vertical line VL. FIG. 5E shows the case in which both the first angle CA1 and the second angle CA2 are each less than the second reference angle.

Referring to FIGS. 4 and 5F, the first OPC pattern for the corrected transition area TA is calculated in operation S167. In FIG. 5F, a line OPC-PL of the first OPC pattern corresponding to a horizontal line HL and a vertical line VL on the corrected transition area TA is indicated by a dark hatched line. In FIG. 5F, horizontal edges HE1 and HE2 (lightly hatched) of the OPC pattern corresponding to the existing first and second edge lines EL1 and EL2 and horizontal edges HE1′ and HE2′ of the first OPC pattern corresponding to the corrected first and second edge lines EL1 and EL2 are shown together. The horizontal edges HE1′ and HE2′ of the first OPC pattern may include a first horizontal edge HE1′ and a second horizontal edge HE2′ correspondingly to the moved first and second edge lines EL1 and EL2.

After the first OPC pattern is calculated, the method proceeds to operation S140 of obtaining the simulation contour. In operation S140 of obtaining the simulation contour, the simulation contour may be obtained again for the first OPC pattern of the corrected transition area TA. As seen from FIG. 5F, a new simulation contour Con3 is shown, and the new simulation contour Con3 changes more steeply relative to the vertical line VL compared to the previous simulation contour Con.

In one or more embodiments, the operation of calculating the correction angle and the operation of obtaining the first OPC pattern based on the correction angle may be performed prior to the operation of calculating the correction length and the operation of obtaining the first OPC pattern based on the correction length. In one or more embodiments, the operation of calculating the correction angle and the operation of obtaining the first OPC pattern based on the correction angle may be performed alone without the operation of calculating the correction length and the operation of obtaining the first OPC pattern based on the correction length. In one or more embodiments, the operation of calculating the correction length and the operation of obtaining the first OPC pattern based on the correction length may be performed alone, and the operation of calculating the correction angle and the operation of obtaining the first OPC pattern based on the correction angle may be omitted.

In the OPC method according to the present disclosure, the baseline OPC may be performed to obtain the OPC pattern for the target pattern including the transition area, the transition area may be extracted from the target pattern to calculate at least one of the correction length and the correction angle, the first OPC pattern for the transition area may be obtained based on at least one of the correction length and the correction angle, and the first OPC pattern may be merged with the OPC pattern to obtain the final OPC pattern. As such, an additional first OPC pattern may be obtained by correcting the transition area using the correction length and the correction angle and may be applied to the entire OPC pattern, and thus the simulation contour may be implemented more stiffly to minimize a CRR, thereby ensuring a sufficient processing margin in the transition area.

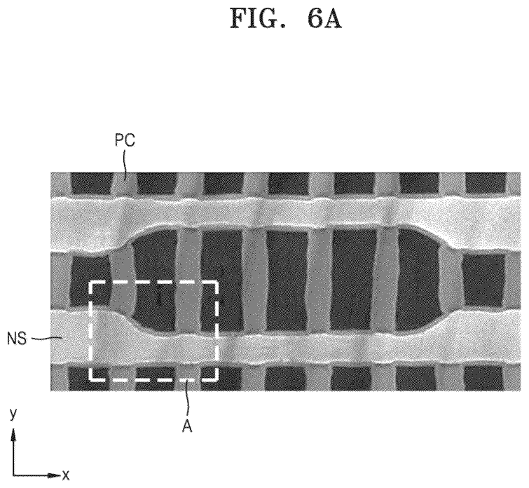

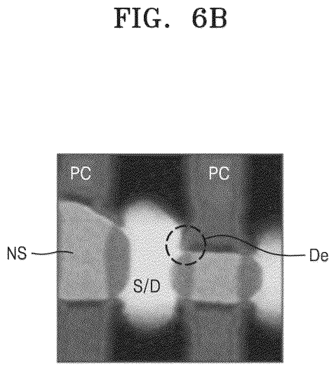

FIGS. 6A and 6B are, respectively, a transmission electron microscope (TEM) image and an enlarged TEM image of detailed patterns to which an OPC method according to the present disclosure is applicable. More specifically, FIG. 6B is an enlarged TEM image of a portion A of FIG. 6A.

Referring to FIGS. 6A and 6B, in FIG. 6A, a nanosheet NS corresponding to the target pattern TP in FIG. 6A may extend in the x direction and may include a transition area, the width of which is narrowed. For example, in FIG. 6A, the portion A indicated with a dashed square may correspond to the transition area. A gate line PC corresponding to the line pattern may extend in the y direction and may be placed with a constant pitch in the x direction.

As seen from the enlarged TEM image of FIG. 6B, in the transition area, the gate line PC on the right intersects with a source/drain area S/D at an acute angle, and accordingly, a defect De may occur in a portion indicated by a dashed circle. For example, a short-circuit defect in which polysilicon of the gate line PC is connected to silicon germanium of the source/drain area S/D may occur. Therefore, to prevent the defect, it is necessary to increase an angle at which the gate line PC and the source/drain area S/D intersect with each other. In the OPC method according to the present disclosure, the transition area may be corrected based on the correction length and/or the correction angle to implement the simulation contour more stiffly, and thus a CRR in the transition area may be minimized to increase a processing margin and prevent defects.

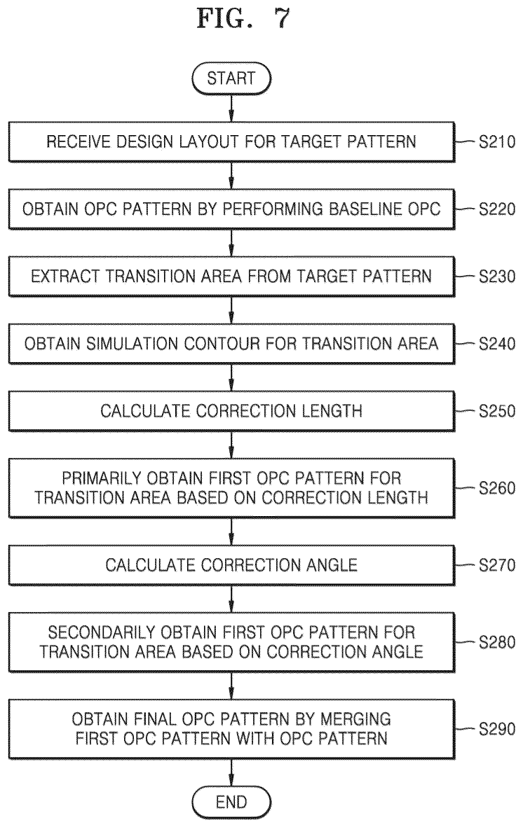

FIG. 7 is a schematic flowchart of processes of an OPC method according to an embodiment. The method will be described with reference to the drawing with FIGS. 1 to 5F, and content already explained in the description of FIGS. 1 and 6B is briefly explained or omitted.

Referring to FIG. 7, in the OPC method according to the present disclosure, operation S210 of receiving a design layout of a target pattern through operation S240 of obtaining a simulation contour for a transition area are sequentially performed. Operation S210 of receiving the design layout of the target pattern to operation S240 of obtaining the simulation contour for the transition area are the same as the description of operation S110 of receiving the design layout of the target pattern to operation S140 of obtaining the simulation contour of the transition area in the OPC method of FIG. 1.

Operation S250 of calculating a correction length and operation S260 of primarily obtaining the first OPC pattern based on the correction length may be performed. Operation S250 of calculating the correction length and operation S260 of primarily obtaining the first OPC pattern based on the correction length are the same as the description of FIGS. 2 to 3C.

Subsequently, operation S270 of calculating the correction angle and operation S280 of secondarily obtaining the first OPC pattern based on the correction angle may be performed. Operation S270 of calculating the correction angle and operation S280 of secondarily obtaining the first OPC pattern based on the correction angle are the same as the description of FIGS. 4 through 5F. As used herein, the terms “primarily” and “secondarily” are used to refer to an order of operations between obtaining the first OPC pattern based on the correction length and obtaining the first OPC pattern based on the correction angle, whereby “primarily obtaining” occurs prior to “secondarily obtaining.”

After the first OPC pattern is secondarily obtained, the first OPC pattern is merged with the OPC pattern to obtain a final OPC pattern (S290).

As a result, the OPC method according to the present disclosure may correspond to the case in which operation S160 of obtaining the first OPC pattern for the transition area is performed in combination, and may also correspond to the case in which, first, the correction length is calculated and the first OPC pattern for the transition area is obtained based on the correction length, and then the correction angle is calculated and the first OPC pattern for the transition area is obtained based on the correction angle.

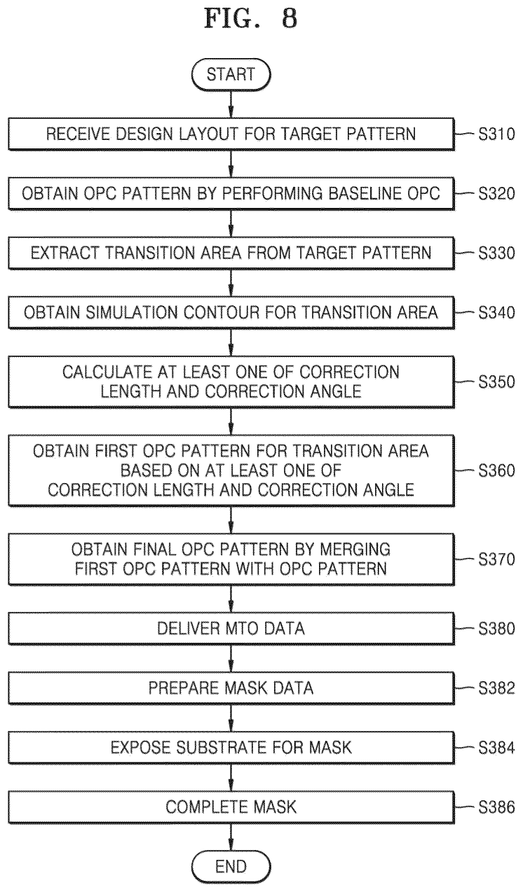

FIG. 8 is a schematic flowchart of processes of a mask manufacturing method including an OPC method according to an embodiment. The method will be described with reference to the drawing with FIGS. 1 to 5F and 7, and content already explained in the description of FIGS. 1 and 7 is briefly explained or omitted.

Referring to FIG. 8, in a mask manufacturing method including an OPC method according to the present disclosure (hereinafter referred to as a “mask manufacturing method”), operation S310 of receiving a design layout for a target pattern through operation S370 of obtaining a final OPC pattern are sequentially performed. Operation S310 of receiving the design layout of the target pattern to operation S370 of obtaining the final OPC pattern are the same as the description of operation S110 of receiving the design layout of the target pattern to operation S170 of obtaining the final OPC pattern in the OPC method of FIG. 1.

Then, MTO design data is handed over to a mask production team (S380). In general, the MTO may mean that data on a final design layout obtained through an OPC method is handed over to a mask production team to request mask production. Thus, in the mask manufacturing method according to the present disclosure, the MTO design data may eventually mean the final OPC pattern obtained through the OPC method, that is, an OPCed design layout, or data thereon. The MTO design data may have graphic data formats used in electronic design automation (EDA) software. For example, MTO design data may have data formats such as Graphic Data System II (GDS2) or Open Artwork System Interchange Standard (OASIS).

Then, mask data preparation (MDP) is performed (S382). The MDP may include, for example, i) format conversion called fracturing, ii) augmentation of a barcode for mechanical reading, standard mask patterns for inspection, job deck, and the like, and iii) verification of an automatic and manual method. The job deck may mean generation of a text file about a series of commands of arrangement information of multi-mask files, reference dose, or an exposure speed or method.

Format conversion, that is, fracturing, may mean a process of dividing the MTO design data for each area and changing the data to a format for an electron beam exposure device. Fracturing may include a data operation such as scaling, sizing of data, rotation of data, pattern reflection, or color reversal. In a conversion process through fracturing, data for numerous systematic errors that occur at any points while design data is transferred to an image on a wafer may be corrected.

A data correction process for systematic errors may be called mask process correction (MPC), and for example, may include line width adjustment called DC adjustment and an operation of increasing pattern arrangement precision. Thus, fracturing may be a process that contributes to quality improvement of a final mask and is proactively performed for MPC. Systematic errors may be caused by distortions that occur in an exposure process, a mask development and etching process, and a wafer imaging process.

The MDP may include the MPC. The MPC may refer to a process of correcting errors that occur in the exposure process, that is, systematic errors as described above. The exposure process may be an overall concept that includes electronic beam writing, development, etching, and bake. Data processing may be performed prior to the exposure process. Data processing is a preprocessing procedure for a kind of mask data and may include grammar checks for mask data and exposure time predictions.

After the MDP, a substrate for a mask is exposed based on the mask data (S384). Exposure may mean, for example, electron beam writing. The electron beam writing may be performed, for example, in a gray writing method using a multi-beam mask writer (MBMW). The electron beam writing may also be performed using a variable shape beam (VSB) exposure device.

After the MDP, an operation of converting mask data into pixel data may be performed prior to the exposure process. The pixel data may be data used directly in actual exposure and may include data on a shape of an exposure target and data on a dose assigned thereto. The data on the shape may be bit-map data obtained by conversion of shape data as vector data through rasterization.

After the exposure process, the mask is completed by performing a series of processes (S386). The series of processes may include, for example, development, etching, and cleaning. The series of processes for mask manufacturing may include measurement processes, defect inspections, or defect repair processes. The series of processes for mask manufacturing may include a pellicle coating process. The pellicle coating process may mean a process of attaching pellicles to protect a mask from subsequent contamination of a mask surface during delivery of the mask and a useful lifetime of the mask when it is confirmed that there are no contaminations or chemical stains through final cleaning and inspection.

While the disclosure has been particularly shown and described with reference to embodiments thereof, it will be understood that various changes in form and details may be made therein without departing from the spirit and scope of the following claims. Therefore, the true technical scope of the disclosure may be determined by the technical spirit the claims.

While the disclosure has been particularly shown and described with reference to embodiments thereof, it will be understood that various changes in form and details may be made therein without departing from the spirit and scope of the following claims.

What is claimed is:

1. An optical proximity correction (OPC) method comprising:
receiving a design layout for a target pattern;
obtaining an OPC pattern by performing first OPC on the design layout;
extracting a transition area from the target pattern, wherein the transition area comprises a width that changes from a first width in a first portion to a second width in a second portion, and the second width is less than the first width;
obtaining a simulation contour for the transition area;
calculating at least one of a correction length and a correction angle based on the simulation contour;
obtaining a first OPC pattern for the transition area based on at least one of the correction length and the correction angle; and
obtaining a final OPC pattern by merging the first OPC pattern with the OPC pattern,
wherein the first portion comprises a common lower horizontal line extending in a first direction, a first upper horizontal line parallel to the common lower horizontal line, and a vertical line extending in a second direction from an end of the first upper horizontal line,
wherein the second direction intersects the first direction,
wherein the second portion is in contact with the first portion and comprises the common lower horizontal line and a second upper horizontal line parallel to the common lower horizontal line and connected to the vertical line, and
wherein the first width and the second width are distances from the common lower horizontal line to the first upper horizontal line and from the common lower horizontal line to the second upper horizontal line, respectively.

2. The OPC method of claim 1, wherein the correction length is calculated as a distance in the first direction between two points having a reference length extraction angle set for the vertical line based on a tangent line for the simulation contour,
wherein the correction angle is calculated as an angle between the tangent line of the simulation contour and two extraction line patterns among line patterns that extend in the second direction and are arranged with a constant pitch in the first direction, and
wherein the calculating of the at least one of the correction length and the correction angle further comprises calculating both the correction length and the correction angle.

3. The OPC method of claim 2, wherein the obtaining the first OPC pattern comprises:
primarily obtaining the first OPC pattern based on the correction length; and
secondarily obtaining the first OPC pattern based on the correction angle.

4. The OPC method of claim 1, wherein the calculating of the at least one of the correction length and the correction angle comprises calculating the correction length,
wherein the correction length is calculated as a distance in the first direction between two points having a reference length extraction angle set for the vertical line based on a tangent line for the simulation contour, and
wherein the obtaining of the first OPC pattern comprises correcting the transition area, and
wherein the correcting of the transition area comprises:
based on the correction length being greater than or equal to a set reference length, calculating a correction amount based on Equation 1 below:
correction amount=FB*(correction length−reference length)/2, Equation 1:
wherein FB comprises a set feedback factor,
dividing the vertical line into an upper vertical line and a lower vertical line, and
adjusting the upper vertical line toward the second portion by the correction amount, and adjusting the lower vertical line toward the first portion by the correction amount.

5. The OPC method of claim 4, wherein the obtaining of the first OPC pattern further comprises, after the correcting of the transition area, calculating the first OPC pattern for the transition area,
wherein the obtaining of the simulation contour is performed after the obtaining of the first OPC pattern, and
wherein the method further comprises, based on a correction length that is newly calculated through the simulation contour being greater than the reference length and less than an immediately previous correction length by 1 nm or more, repeating the calculating of the at least one of the correction length and the correction angle and the obtaining of the first OPC pattern.

6. The OPC method of claim 1, wherein the calculating of the at least one of the correction length and the correction angle comprises calculating the correction angle,
wherein the calculating the correction angle comprises calculating a first angle and a second angle between a tangent line of the simulation contour and a first line pattern and a second line pattern among a plurality of line patterns that extend in the second direction and are arranged with a constant pitch in the first direction,
wherein, based on a center of a central line pattern from among the plurality of line patterns matches the vertical line, the first line pattern is first arranged to a left of the central line pattern and the second line pattern is first arranged to a right of the central line pattern,
wherein the obtaining the first OPC pattern comprises correcting the vertical line of the transition area, and
wherein the correcting of the vertical line of the transition area comprises, based on a difference between the first angle and the second angle being greater than or equal to a set first reference angle, moving the vertical line by a set distance toward a larger angle of the first angle and the second angle.

7. The OPC method of claim 6, wherein the obtaining the first OPC pattern further comprises, after the correcting of the vertical line of the transition area, calculating the first OPC pattern for the transition area,
wherein the obtaining the simulation contour is performed after the obtaining of the first OPC pattern, and
wherein the method further comprises, based on a difference between the first angle and the second angle, which are newly calculated through the simulation contour, being greater than or equal to the set first reference angle, repeating the calculating the at least one of the correction length and the correction angle and the obtaining the first OPC pattern.

8. The OPC method of claim 6, wherein the obtaining the first OPC pattern further comprises, after the correcting the vertical line of the transition area, correcting a horizontal line of the transition area,
wherein the correcting the horizontal line of the transition area comprises:
setting a first edge line of the first upper horizontal line between the central line pattern and the first line pattern, and a second edge line of the second upper horizontal line between the central line pattern and the second line pattern; and
based on at least one of the first angle and the second angle being less than a set second reference angle, moving the at least one of the first angle and the second angle in the second direction away from the vertical line.

9. The OPC method of claim 8, wherein the obtaining the first OPC pattern further comprises, after the correcting of the horizontal line of the transition area, calculating the first OPC pattern for the transition area,
wherein the obtaining the simulation contour is performed after the obtaining of the first OPC pattern, and
wherein the method further comprises, based on at least one of the first angle and the second angle, which are newly calculated through the simulation contour, being less than the set second reference angle, repeating the calculating of the at least one of the correction length and the correction angle and the obtaining of the first OPC pattern.

10. The OPC method of claim 9, wherein the method further comprises:
based on at least one of the first angle and the second angle, which are newly calculated through the simulation contour, being less than the set second reference angle, and also based on each of the first angle and the second angle being consecutively changed three times and being equal to or less than a certain angle, the calculating the at least one of the correction length and the correction angle and the obtaining of the first OPC pattern are not performed.

11. An optical proximity correction (OPC) method comprising:
receiving a design layout for a target pattern;
obtaining an OPC pattern by performing first OPC on the design layout;
extracting a transition area from the target pattern, wherein the transition area comprises a width that changes from a first width in a first portion to a second width in a second portion, and the second width is less than the first width;
obtaining a simulation contour for the transition area;
calculating a correction length based on the simulation contour;
primarily obtaining a first OPC pattern for the transition area based on the correction length;
calculating a correction angle based on the simulation contour;
secondarily obtaining the first OPC pattern for the transition area based on the correction angle; and
obtaining a final OPC pattern by merging the first OPC pattern with the OPC pattern,
wherein the first portion comprises a common lower horizontal line extending in a first direction, a first upper horizontal line parallel to the common lower horizontal line, and a vertical line extending in a second direction from an end of the first upper horizontal line,
wherein the second direction intersects the first direction,
wherein the second portion is in contact with the first portion and comprises the common lower horizontal line and a second upper horizontal line parallel to the common lower horizontal line and connected to the vertical line, and
wherein the first width and the second width are distances from the common lower horizontal line to the first upper horizontal line and from the common horizontal line to the second upper horizontal line, respectively.

12. The OPC method of claim 11, wherein the correction length is calculated as a distance in the first direction between two points having a reference length extraction angle set for the vertical line based on a tangent line for the simulation contour,
wherein the primarily obtaining the first OPC pattern comprises:
based on the correction length being greater than or equal to a set reference length, calculating a correction amount based on Equation 1 below:
correction amount=FB*(correction length−reference length)/2, Equation 1:
wherein the FB being a set feedback factor,
dividing the vertical line is equally divided into an upper vertical line and a lower vertical line, and
adjusting the upper vertical line toward the second portion by the correction amount and adjusting the lower vertical line toward the first portion by the correction amount.

13. The OPC method of claim 11, wherein the calculating the correction angle comprises calculating a first angle and a second angle between a tangent line of the simulation contour and a first line pattern and a second line pattern among a plurality of line patterns that extend in the second direction and are arranged with a constant pitch in the first direction,
wherein, based on a center of a central line pattern from among the plurality of line patterns matches the vertical line, the first line pattern is first arranged to a left of the central line pattern, and the second line pattern is first arranged to a right of the central line pattern, and
wherein the secondarily obtaining the first OPC pattern comprises:
based on a difference between the first angle and the second angle being greater than or equal to a set first reference angle, moving the vertical line by a set distance toward a larger angle of the first angle and the second angle.

14. The OPC method of claim 13, further comprising:
setting a first edge line of the first upper horizontal line between the central line pattern and the first line pattern, and a second edge line of the second upper horizontal line between the central line pattern and the second line pattern,
wherein, based on at least one of the first angle and the second angle being less than a set second reference angle, moving the at least one the first angle and the second angle in the second direction away from the vertical line.

15. A mask manufacturing method comprising:
receiving a design layout for a target pattern;
obtaining an optical proximity correction (OPC) pattern by performing first OPC on the design layout;
extracting a transition area from the target pattern, wherein the transition area comprises a width that changes from a first width in a first portion to a second width in a second portion, and wherein the second width is less than the first width;
obtaining a simulation contour for the transition area;
calculating at least one of a correction length and a correction angle based on the simulation contour;
obtaining a first OPC pattern based on the at least one of the correction length and the correction angle;
obtaining a final OPC pattern by merging the first OPC pattern with the OPC pattern;
transferring data on the final OPC pattern as mask tape-out (MTO) design data;
preparing mask data based on the MTO design data; and
performing exposure on a substrate for a mask based on the mask data.

16. The mask manufacturing method of claim 15,
wherein the first portion comprises a common lower horizontal line extending in a first direction, a first upper horizontal line parallel to the common lower horizontal line, and a vertical line extending in a second direction from an end of the first upper horizontal line,
wherein the second direction intersects the first direction,
wherein the second portion is in contact with the first portion and comprises the common lower horizontal line and a second upper horizontal line parallel to the common lower horizontal line and connected to the vertical line,
wherein the first width and the second width are distances from the common lower horizontal line to the first upper horizontal line and from the common lower horizontal line and the second upper horizontal line, respectively,
wherein the correction length is calculated as a distance in the first direction between two points having a reference length extraction angle set for the vertical line based on a tangent line for the simulation contour, and
wherein the correction angle is calculated as a first angle and a second angle between the tangent line of the simulation contour and first and second line patterns from among a plurality of line patterns that extend in the second direction and are arranged with a constant pitch in the first direction.

17. The mask manufacturing method of claim 16, wherein the calculating the at least one of the correction length and the correction length comprises calculating both the correction length and the correction angle, and
wherein the obtaining the first OPC pattern comprises:
primarily obtaining the first OPC pattern based on the correction length, and
secondarily obtaining the first OPC pattern based on the correction angle.

18. The mask manufacturing method of claim 16, wherein the obtaining the first OPC pattern comprises:
based on the correction length being greater than or equal to a set reference length, calculating a correction amount based on Equation 1 below:
correction amount=FB*(correction length−reference length)/2, Equation 1:
wherein the FB being a set feedback factor, and
dividing the vertical line is equally into an upper vertical line and a lower vertical line, and
adjusting the upper vertical line toward the second portion by the correction amount and adjusting the lower vertical line toward the first portion by the correction amount.

19. The mask manufacturing method of claim 16, wherein, based on a center of a central line pattern from among the plurality of line patterns matches the vertical line, a first line pattern is first arranged to a left of the central line pattern and a second line pattern is first arranged to a right of the central line pattern, and
wherein the obtaining the first OPC pattern comprises:
based on a difference between the first angle and the second angle being greater than or equal to a set first reference angle, moving the vertical line by a set distance toward a larger angle of the first angle and the second angle.

20. The mask manufacturing method of claim 19, further comprising:
setting a first edge line of the first upper horizontal line between the central line pattern and the first line pattern, and a second edge line of the second upper horizontal line between the central line pattern and the second line pattern; and
based on at least one of the first angle and the second angle being less than a set second reference angle, moving the at least one of the first angle and the second angle in the second direction away from the vertical line.
